(19) United States
(12) Patent Application Publication
(10) Pub. No.: US 2026/0096018 A1
(43) Pub. Date: Apr. 2, 2026

(54) ELECTRONIC DEVICE AND METHOD FOR MANUFACTURING THE SAME

(71) Applicant: Innolux Corporation, Miaoli County (TW)

(72) Inventors: Ju-Li Wang, Miaoli County (TW); Wen-Hsiang Liao, Miaoli County (TW); Jeng-Nan Lin, Miaoli County (TW); Ker-Yih Kao, Miaoli County (TW)

(73) Assignee: Innolux Corporation, Miaoli County (TW)

(21) Appl. No.: 19/315,684

(22) Filed: Sep. 1, 2025

Related U.S. Application Data
(60) Provisional application No. 63/702,099, filed on Oct. 1, 2024.

(30) Foreign Application Priority Data
May 16, 2025 (CN) 202510633876.8

(51) Int. Cl. H05K 1/02; H05K 1/18; H05K 3/36

(52) U.S. Cl. CPC H05K 1/0271; H05K 1/181; H05K 3/36; H05K 2201/068; H05K 2201/10159; H05K 2201/10378; H05K 2201/10515; H05K 2201/10522; H05K 2203/016; H05K 2203/166

(57) ABSTRACT

The present disclosure provides an electronic device and a method for manufacturing the same, in which the method includes the following steps. A substrate structure is provided, wherein the substrate structure includes a first substrate and a second substrate. A first anti-warpage layer is provided on at least one side of the substrate structure. A first circuit structure is formed on the first substrate. A packaging structure is formed on the first circuit structure, wherein the first substrate is disposed between the first circuit structure and the second substrate, and the coefficient of thermal expansion of the first substrate is greater than the coefficient of thermal expansion of the second substrate.

### CROSS-REFERENCE TO RELATED APPLICATION

This application claims the priority benefit of U.S. provisional application serial no. 63/702,099, filed on October 1, 2024, and China application serial no. 202510633876.8, filed on May 16, 2025. The entirety of each of the above-mentioned patent applications is hereby incorporated by reference herein and made a part of this specification.

### BACKGROUND

### Technical Field

The disclosure relates to an electronic device and a method for manufacturing the same, and more particularly to an electronic device with an improved warpage and a method for manufacturing the same.

### Description of Related Art

A panel-level package (PLP), including a technique such as a fan-out panel-level package (FOPLP), may enhance the integration density of electronic elements including active elements such as transistors or diodes and/or passive elements such as resistors or capacitors in a given region, and thus has been widely applied in the manufacture of electronic devices in recent years.

The process for the panel-level package may use a carrier substrate with a large area for producing the circuits, which is beneficial for enhancing the yield and/or lowering the cost for manufacturing the package unit. However, since different materials used to form the package structure of the electronic elements have different physical properties (e.g., coefficient of thermal expansion (CTE)), so that the manufactured package structure in such situation is prone to have a warpage. Under large-scale production conditions, the warpage of the package structure will become more significant, and thereby causes issues such as misalignment during the manufacturing process. Accordingly, when applied to the electronic elements, it is easy to have problems such as short circuits and/or abnormal signal transmissions in the circuit structure of the electronic elements, so that the reliability and electrical performance of the manufactured electronic elements may be decreased.

Therefore, those skilled in the art are still continuously making improvements to improve the warpage problem in order to meet the needs in the present or in the future.

### SUMMARY

The present disclosure provides an electronic device and a method for manufacturing the same, which can improve warpage by adjusting the coefficient of thermal expansion (CTE) of the substrate structure, and thus is beneficial for enhancing the reliability of the electronic device.

According to an embodiment of the present disclosure, a method for manufacturing an electronic device includes the following steps. A substrate structure is provided, wherein the substrate structure includes a first substrate and a second substrate. A first anti-warpage layer is provided on at least one side of the substrate structure. A first circuit structure is formed on the first substrate. A package structure is formed on the first circuit structure, wherein the first substrate is disposed between the first circuit structure and the second substrate, and a CTE of the first substrate is greater than a CTE of the second substrate.

According to an embodiment of the present disclosure, an electronic device includes a substrate structure, a first anti-warpage layer, a first circuit structure, and a package structure. The substrate structure includes a first substrate and a second substrate. The first anti-warpage layer is disposed on at least one side of the substrate structure. The first circuit structure is disposed on the first substrate. The package structure is disposed on the first circuit structure. The first substrate is disposed between the first circuit structure and the second substrate, and a CTE of the first substrate is greater than a CTE of the second substrate.

Based on the above, in the embodiments of the present disclosure, the CTE of the first substrate disposed between the first circuit structure and the second substrate is configured to be greater than the CTE of the second substrate, so that the first substrate, the second substrate, and the first circuit structure exhibit a gradual change in CTE, and thus is beneficial for reducing the warpage caused by the excessive difference in CTE, so as to improve the reliability of the electronic device.

To make the features and advantages of the disclosure more comprehensible, several embodiments accompanied with drawings are described in detail as follows.

### BRIEF DESCRIPTION OF THE DRAWINGS

The drawings are included for further understanding of the disclosure, and the drawings are incorporated into and constitute a part of the present specification. The drawings illustrate embodiments of the disclosure and, together with the description, are used to explain the principles of the disclosure.

FIG. 1 is a schematic cross-sectional view of an electronic device according to an embodiment of the present disclosure.

FIG. 2A is a schematic cross-sectional view of the substrate structure in FIG. 1 according to the first embodiment of the present disclosure.

FIG. 2B is a schematic cross-sectional view of the substrate structure in FIG. 1 according to the second embodiment of the present disclosure.

FIG. 2C is a schematic cross-sectional view of the substrate structure in FIG. 1 according to the third embodiment of the present disclosure.

FIG. 2D is a schematic cross-sectional view of the substrate structure in FIG. 1 according to the fourth embodiment of the present disclosure.

FIG. 3A is a schematic cross-sectional view showing a method for manufacturing an electronic device according to an embodiment of the present disclosure.

FIG. 3B is a schematic cross-sectional view showing a method for manufacturing an electronic device according to another embodiment of the present disclosure.

FIG. 4 is a schematic cross-sectional view of an electronic device according to another embodiment of the present disclosure.

FIG. 5A to FIG. 5E are schematic cross-sectional views showing a method for manufacturing an electronic device according to yet another embodiment of the present disclosure.

FIG. 6 is a schematic cross-sectional view of an electronic device according to yet another embodiment of the present disclosure.

FIG. 7 is a schematic cross-sectional view of an electronic device according to still another embodiment of the present disclosure.

### DESCRIPTION OF THE EMBODIMENTS

The disclosure may be understood by referring to the following detailed description in conjunction with the drawings. It should be noted that, in order to allow readers to easily understand and for the sake of simplicity of the drawings, multiple drawings in the disclosure show just a part of a package structure, and specific elements in the drawings are not drawn according to actual proportions. In addition, the quantity and size of elements in the drawings are merely illustrative and are not intended to limit the scope of the disclosure. For example, for the sake of clarity, relative sizes, thicknesses, and positions of respective film layers, regions, and/or structures may be reduced or enlarged.

Throughout the present specification and the appended claims, certain terms are used to refer to specific elements. A person skilled in the art should understand that manufacturers of electronic devices may refer to the same elements by different names. This document does not intend to distinguish elements that have the same function but different names. In the following description and the claims, words such as “have” and “comprise” are open-ended terms, and therefore should be interpreted as meaning “including but not limited to...”.

In this document, “an element is disposed on another element” is used to conveniently describe the relative position between the element and the another element, and is not intended to limit the process steps or sequence of the element and the another element.

Directional terms mentioned in the present document, such as “upper,” “lower,” “front,” “rear,” “left,” “right,” and the like, are for referencing the directions shown in the drawings. Therefore, the directional terms used are for explanation and are not intended to limit the disclosure. It should be understood that when an element or a film layer is described as being “on” another element or film layer or “connected to” another element or film layer, the element or film layer may be directly on or directly connected to the another element or film layer, or there may be an intervening element or film layer (i.e., an indirect case) between the two. Conversely, when an element or film layer is described as being “directly” on another element or film layer or “directly connected to” another element or film layer, no intervening element or film layer exists between the two. In addition, when an element or film layer is described as overlapping another element or film layer, the element or film layer at least partially overlaps the another element or film layer.

The terms “about,” “approximately,” “substantially,” or “roughly” mentioned in the present document generally represent being within 10% of a given value or range, or being within 5%, 3%, 2%, 1%, or 0.5% of the given value or range. In addition, the phrase “a given range is from a first value to a second value” or “a given range falls within a range from a first value to a second value” means that the given range includes the first value, the second value, and other values between them.

In some embodiments of the disclosure, connection or engagement terms such as “connected,” “interconnected,” and the like, unless otherwise specifically defined, may refer to a case where two structures are in direct contact or may refer to a case where two structures are not in direct contact and there is another structure disposed between the two structures. Connection or engagement terms may also include cases where both structures are movable or both structures are fixed. In addition, the terms “electrically connected” and “coupled to” include any direct and indirect electrical connection means.

In the following embodiments, the same or similar elements will be denoted by the same or similar reference numerals, and redundant descriptions thereof will be omitted. In addition, features in different embodiments may be arbitrarily combined and used as long as they do not violate or conflict with the spirit of the invention, and simple equivalent changes and modifications made according to the present specification or the claims still fall within the scope of the disclosure. That is, the following embodiments may involve replacing, reorganizing, or combining technical features of several different embodiments to achieve other embodiments without departing from the spirit of the disclosure. Furthermore, the terms “first,” “second,” and the like mentioned in the present specification or the claims are merely used to designate different elements or distinguish different embodiments or ranges, and are not intended to limit an upper or lower limit on the number of elements, nor are they intended to limit a manufacturing sequence or arrangement order of elements.

In the present disclosure, the thickness, length, and width may be obtained through a measurement using an optical microscope (OM) and/or a scanning electron microscope (SEM), but are not limited thereto. For example, the measurement methods for thickness, length, and width may adopt optical microscope measurement, and thickness or width may be measured from cross-sectional images in an electron microscope, but are not limited thereto. Additionally, any two values or directions used for comparison may have a certain error. If a first value equals a second value, it implies that there may be an error of about 10% between the first value and the second value.

The manufacturing process of the electronic device in this disclosure may be applied, for example, in a panel-level package (PLP) process, and may be a chip-first process or a chip-last-RDL-first process. The electronic device described in this disclosure may be applied to power modules, semiconductor package devices, optical communication modules, display devices, light-emitting devices, backlight devices, antenna devices, sensing devices or tiled devices, but is not limited thereto.

The following provides exemplary embodiments of the disclosure. The same reference symbols in the drawings and the description are used to represent the same or similar parts.

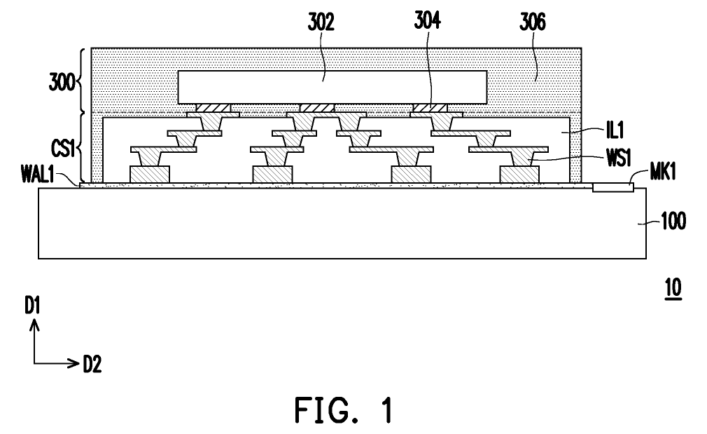

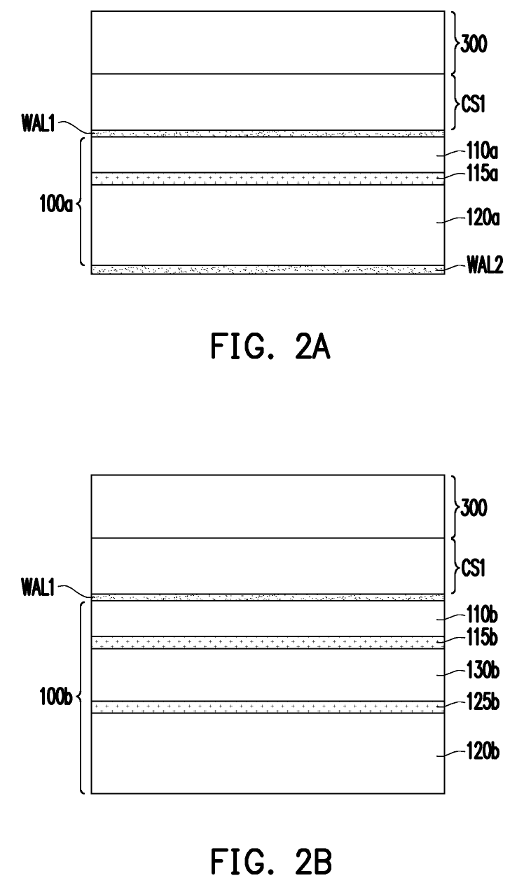

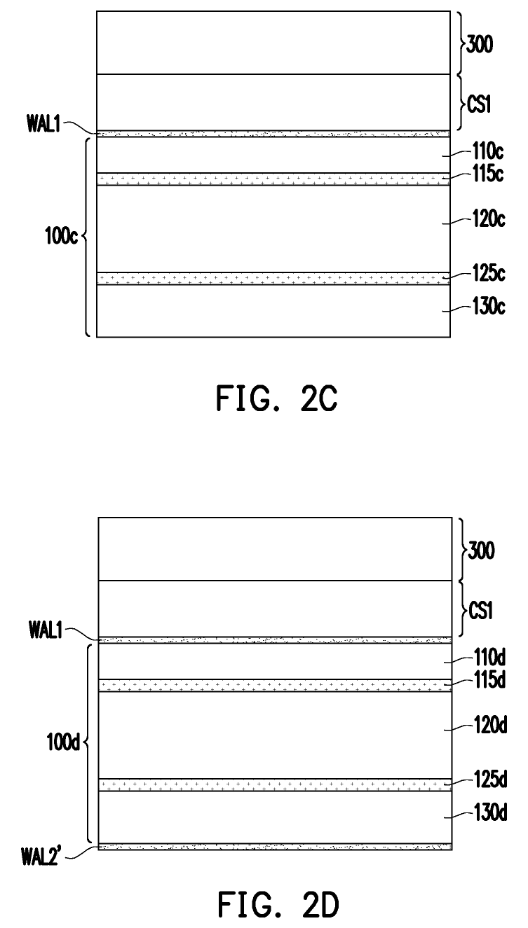

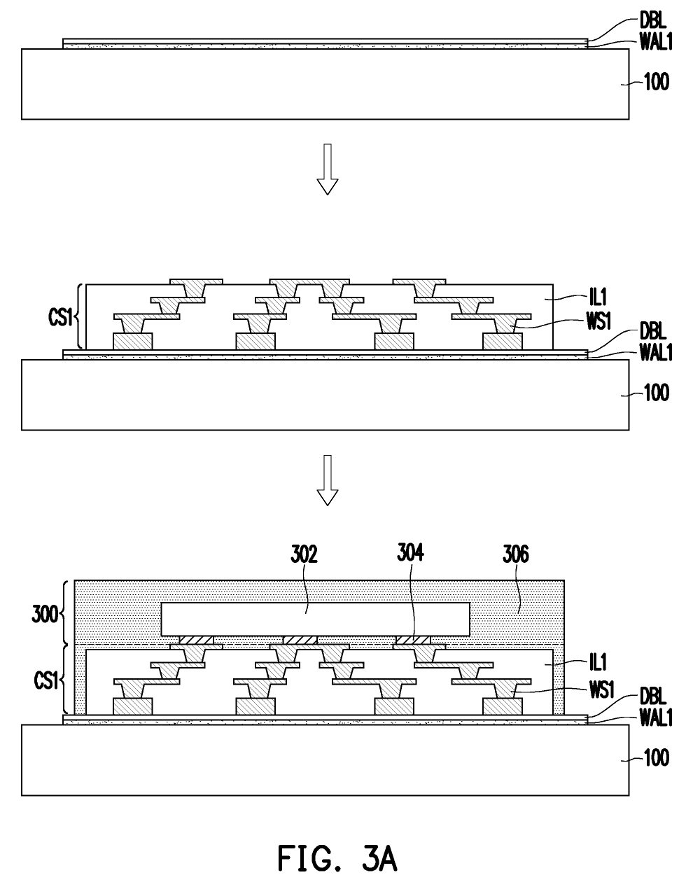

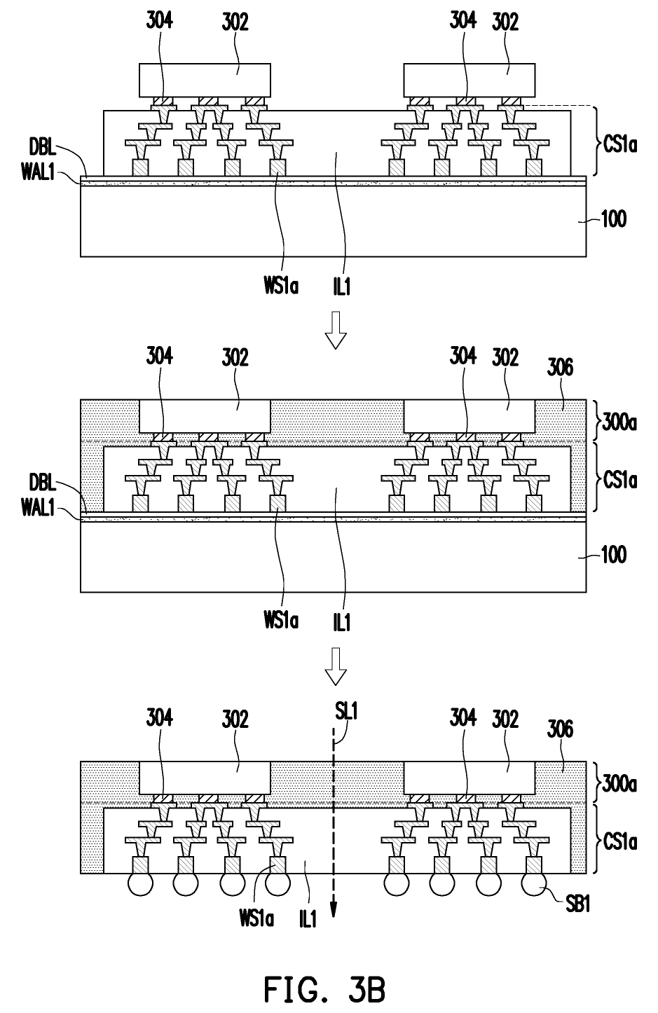

FIG. 1 is a schematic cross-sectional view of an electronic device according to an embodiment of the present disclosure. FIG. 2A is a schematic cross-sectional view of the substrate structure in FIG. 1 according to the first embodiment of the present disclosure. FIG. 2B is a schematic cross-sectional view of the substrate structure in FIG. 1 according to the second embodiment of the present disclosure. FIG. 2C is a schematic cross-sectional view of the substrate structure in FIG. 1 according to the third embodiment of the present disclosure. FIG. 2D is a schematic cross-sectional view of the substrate structure in FIG. 1 according to the fourth embodiment of the present disclosure.

Firstly, referring to FIG. 1, an electronic device 10 includes a substrate structure 100, a first anti-warpage layer WAL1, a first circuit structure CS1, and a package structure 300.

The substrate structure 100 may include a first substrate and a second substrate. For example, as shown in FIG. 2A, the substrate structure 100a may include a first substrate 110a and a second substrate 120a. In the present embodiment, the coefficient of thermal expansion (CTE) of the first substrate 110a is different from the CTE of the second substrate 120a. In some embodiments, the CTE of the first substrate 110a is greater than the CTE of the second substrate 120a. In some embodiments, the CTE of the first substrate 110a is less than the CTE of the second substrate 120a. In some embodiments, the substrate structure 100 may be used to support other elements, but is not limited thereto. In some embodiments, the substrate structure 100 may have panel-level size (i.e., the area of the substrate structure 100 may include a size of 30 cm x 30 cm, 50 cm x 50 cm, 70 cm x 70 cm, or any suitable dimensions, but is not limited thereto). Based on this, the processes to be performed in the subsequent in the present embodiment may be an application of the fan-out panel-level package (FOPLP), wherein the FOPLP includes the aforementioned chip-last-RDL-first process or chip-first process. In the present embodiment, as compared to the wafer-level package, the FOPLP can improve the productivity significantly since the substrate structure 100 used in the process has the panel-level size. Meanwhile, the substrate structure 100 having panel-level size may have a rectangular profile, which can also significantly improve the utilization of the substrate structure 100 compared to the wafer-level package. In some embodiments, the substrate structure 100 may include an alignment mark MK1 for alignment.

The first anti-warpage layer WAL1 may be disposed on at least one side of the substrate structure 100. In some embodiments, the first anti-warpage layer WAL1 may be a single-layer or multi-layer structure including organic materials and/or inorganic materials in which the inorganic materials may include silicon oxide (SiO₂), silicon nitride (SiₓN_{y}), silicon oxynitride (SiOₓN_{y}), or other suitable inorganic materials, but the present disclosure are not limited thereto. In some embodiments, when the first anti-warpage layer WAL1 includes inorganic materials with multi-layer structure, a silicon oxide may be firstly formed on the first substrate 110a, and then a silicon nitride may be provided on the silicon oxide, or alternatively, the silicon nitride may be firstly formed on the first substrate 110a, and then the silicon oxide may be provided on the silicon nitride. The thickness of the silicon oxide may be different from the thickness of the silicon nitride, for example, the thickness of the silicon oxide may be greater than the thickness of the silicon nitride along a direction D1 (e.g., a normal direction of the substrate structure 100). In some embodiments, the first anti-warpage layer WAL1 may have a thickness in a range from 0.5 μm to 3 μm along the direction D1 (e.g., the normal direction of the substrate structure 100).

The first circuit structure CS1 is disposed on the first substrate of the substrate structure 100 (e.g., the first substrate 110a of the substrate structure 100a shown in FIG. 2A). In the present embodiment, the first circuit structure CS1 may include an insulation layer IL1 formed on the first anti-warpage layer WAL1 and a wiring structure WS1 formed in the insulation layer IL1. The insulation layer IL1 may include a plurality of insulation layers alternately stacked along the direction D1. The wiring structure WS1 may include a plurality of conductive patterns/conductive layers formed in the insulation layer IL1 and alternately stacked along the direction D1, and conductive vias connecting to the conductive patterns/conductive layers. The wiring structure WS1 may include any suitable conductive material, for example, copper, titanium, nickel, combinations or alloys of the aforementioned materials, but is not limited thereto. The insulation layer IL1 may include organic materials or inorganic materials. The organic materials include polyimide (PI), poly-p-xylylene (also known as Parylene), benzocyclobutene (BCB), epoxy resin, polycarbonate (PC), polyethylene terephthalate (PET), polyethylene naphthalate (PEN), polymer, or other suitable organic materials, but are not limited thereto. The inorganic materials include silicon oxide, silicon nitride, silicon oxynitride, or other suitable inorganic materials, but are not limited thereto.

In some embodiments, the CTE of the first circuit structure CS1 may be greater than the CTE of the first substrate of the substrate structure 100 (e.g., the first substrate 110a of the substrate structure 100a shown in FIG. 2A), wherein a ratio of the CTE of the first circuit structure CS1 to the CTE of the first substrate 110a of the substrate structure 100 may be greater than or equal to 1.5 and less than or equal to 4. For example, the CTE of the first circuit structure CS1 may be in a range from 15 ppm/K to 20 ppm/K, while the CTE of the first substrate 110a may be in a range from 5 ppm/K to 10 ppm/K. In the present embodiment, the CTE of the first circuit structure CS1 may be calculated by the following manner. The volume occupied by the insulation layer IL1 of the first circuit structure CS1 is V_{A} and has a CTE with a value of CTE_{A}, and the volume occupied by the wiring structure WS1 of the first circuit structure CS1 is V_{B} and has a CTE with a value of CTE_{B}. The CTE of the first circuit structure CS1 may be a sum of V_{A}*(CTE_{A})/(V_{A}+V_{B}) and V_{B}*(CTE_{B})/(V_{A}+V_{B}). For example, the volume occupied by the wiring structure WS1 of the first circuit structure CS1 may be identified through an optical detection instrument or through other suitable manners.

The package structure 300 is disposed on the first circuit structure CS1. In the present embodiment, the package structure 300 includes an electronic element 302, pads 304 disposed on one side of the electronic element 302 and electrically connecting the electronic element 302 to the first circuit structure CS1, and a molding layer 306 encapsulating the electronic element 302 and the pads 304. The electronic element 302 may include a die, a chip, a diode, an antenna, a memory, a photonic integrated circuit (PIC), a sensor, or structures of semiconductor-related processes. The pads 304 may include any suitable conductive material, such as copper (Cu), aluminum (Al), nickel (Ni), molybdenum (Mo), titanium (Ti), alloys or combinations of the aforementioned materials, or other suitable materials, but are not limited thereto. The molding layer 306 may prevent the electronic element 302 from being affected by the external moisture, and thereby improving the reliability of the electronic device 10. The molding layer 306 may include any suitable molding material, such as an epoxy molding compound (EMC), but is not limited thereto. In some embodiments, the molding layer 306 may cover the first anti-warpage layer WAL1 and surround the first circuit structure CS1 to prevent the wiring structure WS1 in the first circuit structure CS1 from being affected by the external moisture, and thereby improving the reliability of the electronic device 10.

In some embodiments, the CTE of the first circuit structure CS1 may be greater than the CTE of the package structure 300. For example, the CTE of the first circuit structure CS1 may be in a range from 15 ppm/K to 25 ppm/K, while the CTE of the package structure 300 may be in a range from 4 ppm/K to 10 ppm/K. In the present embodiment, the CTE of the package structure 300 may be calculated by the following manner. The volume occupied by the molding layer 306 of the package structure 300 is V_{C} and has a CTE with a value of CTE_{C}, the volume occupied by the electronic element 302 of the package structure 300 is V_{D} and has a CTE with a value of CTE_{D}, and the volume occupied by the pads 304 of the package structure 300 is V_{E} and has a CTE with a value of CTE_{E}. The CTE of the package structure 300 may be the sum of V_{C}*(CTE_{C})/(V_{C}+V_{D}+V_{E}), V_{D}*(CTE_{D})/(V_{C}+V_{D}+V_{E}), and V_{E}*(CTE_{E})/(V_{C}+V_{D}+V_{E}).

In the present embodiment, as shown in FIG. 2A, the first substrate 110a is disposed between the first circuit structure CS1 and the second substrate 120a, and the CTE of the first substrate 110a is greater than the CTE of the second substrate 120a. For example, the CTE of the first substrate 110a may be in a range from 5 ppm/K to 10 ppm/K, while the CTE of the second substrate 120a may be in a range from 3 ppm/K to 7 ppm/K. As such, the first substrate 110a, the second substrate 120a, and the first circuit structure CS1 exhibit a gradual change in CTE, and thus is beneficial for reducing the warpage caused by the excessive difference in CTE, so as to improve the reliability of the electronic device 10. According to some embodiments, the warpage direction of the first circuit structure CS1 may be different from the warpage direction of the first anti-warpage layer WAL1. For example, the peripheral region of the first circuit structure CS1 is warped in a direction away from the substrate along the direction D1 (which is similar to a bowl shape), while the peripheral region of the first anti-warpage layer WAL1 is warped in a direction toward the substrate (which is similar to a turtle-shell shape). According to some embodiments, a ratio of the CTE of the first substrate 110a to the CTE of the package structure 300 may be greater than or equal to 0.5 and less than or equal to 2.5, and a ratio of the CTE of the second substrate 120a to the CTE of the package structure 300 may be greater than or equal to 0.3 and less than or equal to 2.

In the present embodiment, since a heating process is conducted during the formation of the first circuit structure CS1, and the CTEs of the insulation layer IL1 and the wiring structure WS1 are both greater than the CTE of the substrate structure 100, the surface of the substrate structure 100 on which the first circuit structure CS1 is disposed tends to warp at its edge toward a direction facing the first circuit structure CS1 (or tends to warp at its center in a direction opposite to the direction facing the first circuit structure CS1), and the first anti-warpage layer WAL1 disposed on at least one side of the substrate structure 100 may be beneficial for mitigating the warpage. For example, the CTE of the first anti-warpage layer WAL1 may be greater than the CTE of the first substrate 110a and may be less than the CTE of the first circuit structure CS1. A such, the first substrate 110a, the second substrate 120a, the first anti-warpage layer WAL1, and the first circuit structure CS1 may exhibit a gradual change in CTE, which is beneficial for reducing the warpage caused by the excessive difference in CTE, so as to improve the reliability of the electronic device 10.

In some embodiments, a ratio of the CTE of the second substrate 120a to the CTE of the package structure 300 including the molding layer 306 may be in a range from 0.7 to 1.2.

In some embodiments, as shown in FIG. 2A, the thickness of the second substrate 120a may be greater than the thickness of the first substrate 110a. In some embodiments, the Young's modulus of the first substrate 110a may be greater than the Young's modulus of the second substrate 120a.

In some embodiments, as shown in FIG. 2A, the substrate structure 100a may further include an intermediate layer 115a disposed between the first substrate 110a and the second substrate 120a. In some embodiments, the intermediate layer 115a may serve as a bonding layer to be beneficial for enhancing the bonding force between the first substrate 110a and the second substrate 120a. In some embodiments, the intermediate layer 115a may include a transparent material, so that a manner such as an ultraviolet de-bonding may be adopted when performing a de-bond process, for example.

In some embodiments, as shown in FIG. 2A, the electronic device 10 may further include a second anti-warpage layer WAL2 disposed on at least another side of the substrate structure 100a to further adjust the CTE of the substrate structure 100a, which is beneficial for reducing the warpage caused by the excessive difference in CTE, so as to improve the reliability of the electronic device 10. In some embodiments, the second anti-warpage layer WAL2 may be a single-layer structure including organic materials, but the present disclosure is not limited thereto. In the present embodiment, the warpage direction of the second anti-warpage layer WAL2 may be the same as the warpage direction of the first anti-warpage layer WAL1. In some embodiments, the CTE of the second anti-warpage layer WAL2 may be less than the CTE of the second substrate 120a, such that the warpage caused by the excessive difference in CTE may be mitigated by exhibiting a gradual change in CTE.

In some other embodiments, as shown in FIG. 2B, the substrate structure 100b may further include a third substrate 130b disposed between the first substrate 110b and the second substrate 120b, wherein the CTE of the third substrate 130b may be greater than the CTE of the second substrate 120b, and the CTE of the first substrate 110b may be greater than the CTE of the third substrate 130b. For example, the CTE of the first substrate 110b may be in a range from 7 ppm/K to 10 ppm/K; the CTE of the second substrate 120b may be in a range from 3 ppm/K to 5 ppm/K; and the CTE of the third substrate 130b may be in a range from 5 ppm/K to 7 ppm/K. As such, the first substrate 110b, the second substrate 120b, the third substrate 130b, and the first circuit structure CS1 exhibit a gradual change in CTE, which is beneficial for reducing the warpage caused by the excessive difference in CTE, so as to improve the reliability of the electronic device 10.

In some embodiments, the thickness of the second substrate 120b may be greater than or equal to the thickness of the third substrate 130b, and the thickness of the third substrate 130b may be greater than or equal to the thickness of the first substrate 110b. In some embodiments, the substrate structure 100b may further include an intermediate layer 115b disposed between the first substrate 110b and the second substrate 120b and an intermediate layer 125b disposed between the second substrate 120b and the third substrate 130b.

In some alternative embodiments, as shown in FIG. 2C, the substrate structure 100c may further include a third substrate 130c in which the second substrate 120c may be disposed between the first substrate 110c and the third substrate 130c. In this embodiment, the CTE of the first substrate 110c may be greater than the CTE of the second substrate 120c, the CTE of the third substrate 130c may be greater than the CTE of the first substrate 110c, and the warpage direction of the third substrate 130c may be opposite to the warpage direction of the first substrate 110c, and thus is beneficial for suppressing the aforementioned warpage. For example, the heating process is conducted during the formation of the first circuit structure CS1, and the CTEs of the insulation layer IL1 and the wiring structure WS1 are both greater than the CTE of the substrate structure 100, so the surface of the substrate structure 100c on which the first circuit structure CS1 is disposed tends to warp at its edges toward a direction facing the first circuit structure CS1 (or tends to warp at its center in a direction opposite to the direction facing the first circuit structure CS1), and the third substrate 130c is configured to have a CTE greater than the CTE of the first substrate 110c and have a warpage direction opposite to the first substrate 110c, such that the surface of the substrate structure 100c on which the first circuit structure CS1 is disposed tends to warp at its edges in a direction toward the other side of the substrate structure 100c (i.e., the side opposite to the side on which the first circuit structure CS1 is disposed), or tends to warp at its center in a direction toward the direction facing the first circuit structure CS1, so that the reliability of the electronic device 10 can be improved by suppressing the warpage.

In some embodiments, the CTE of the first substrate 110c may be in a range of 5 ppm/K to 7 ppm/K; the CTE of the second substrate 120c may be in a range of 3 ppm/K to 5 ppm/K; and the CTE of the third substrate 130c may be in a range of 7 ppm/K to 10 ppm/K. In some embodiments, the thickness of the second substrate 120c may be greater than or equal to the thickness of the third substrate 130c, and the thickness of the third substrate 130c may be greater than or equal to the thickness of the first substrate 110c. In some embodiments, the substrate structure 100c may further include an intermediate layer 115c disposed between the first substrate 110c and the second substrate 120c, and an intermediate layer 125c disposed between the second substrate 120c and the third substrate 130c.

In some other embodiments, as shown in FIG. 2D, the substrate structure 100d may further include a third substrate 130d in which the second substrate 120d may be disposed between the first substrate 110d and the third substrate 130d. In this embodiment, the CTE of the first substrate 110d may be greater than the CTE of the second substrate 120d, the CTE of the third substrate 130d may be greater than the CTE of the first substrate 110d, and the warpage direction of the third substrate 130d may be opposite to the warpage direction of the first substrate 110d, which can improve the reliability of the electronic device 10 by suppressing the warpage issue.

In this embodiment, the electronic device 10 may further include a second anti-warpage layer WAL2' disposed on at least another side of the substrate structure 100d, wherein the warpage direction of the second anti-warpage layer WAL2' is opposite to the warpage direction of the first anti-warpage layer WAL1 (i.e., the same as the warpage direction of the third substrate 130d), which can improve the reliability of the electronic device 10 by suppressing the warpage issue.

In some embodiments, the CTE of the first substrate 110d may be in a range of 5 ppm/K to 7 ppm/K; the CTE of the second substrate 120d may be in a range of 3 ppm/K to 5 ppm/K; and the CTE of the third substrate 130d may be in a range of 7 ppm/K to 10 ppm/K. In some embodiments, the thickness of the second substrate 120d may be greater than or equal to the thickness of the third substrate 130d, and the thickness of the third substrate 130d may be greater than or equal to the thickness of the first substrate 110d. In some embodiments, the substrate structure 100d may further include an intermediate layer 115d disposed between the first substrate 110d and the second substrate 120d, and an intermediate layer 125d disposed between the second substrate 120d and the third substrate 130d.

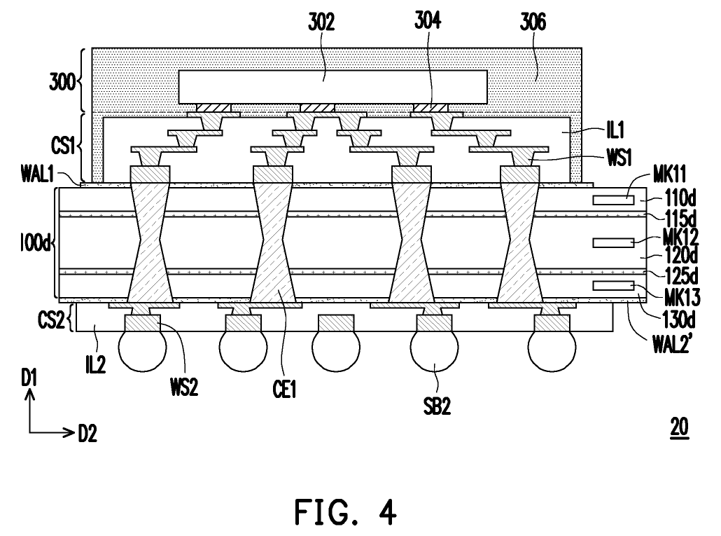

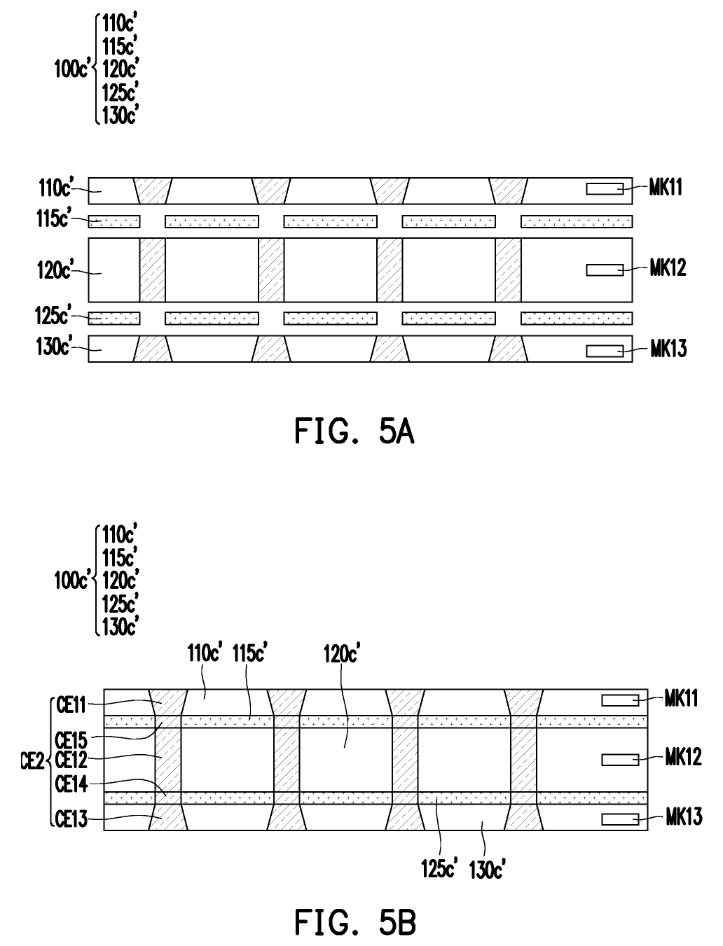

Hereinafter, a method for manufacturing an electronic device will be described with reference to FIG. 3A, but the method for manufacturing the electronic device 10 is not limited thereto.

FIG. 3A is a schematic cross-sectional view showing a method for manufacturing an electronic device according to an embodiment of the present disclosure.

In some embodiments, as shown in FIG. 3A, the method for manufacturing an electronic device may include the following steps. Firstly, a substrate structure 100 is provided. In this embodiment, the substrate structure 100 may include a first substrate and a second substrate (e.g., the first substrates 110a, 110b, 110c, 110d and the second substrates 120a, 120b, 120c, 120d shown in FIG. 2A to FIG. 2D). Next, a first anti-warpage layer WAL1 is provided on at least one side of the substrate structure 100. Then, a de-bond layer DBL is provided on the first anti-warpage layer WAL1. In some embodiments, the de-bond layer DBL may be removed by, for example, an ultraviolet de-bond process or other suitable manners. Thereafter, a first circuit structure CS1 is formed on the first substrate of the substrate structure 100 (e.g., the first substrates 110a, 110b, 110c, 110d shown in FIG. 2A to FIG. 2D). Next, a package structure 300 is formed on the first circuit structure CS1. In this embodiment, as shown in FIG. 2A to FIG. 2D, the first substrate 110a, 110b, 110c, or 110d is disposed between the first circuit structure CS1 and the second substrate 120a, 120b, 120c, or 120d, and the CTE of the first substrate 110a, 110b, 110c, or 110d is greater than the CTE of the second substrate 120a, 120b, 120c, or 120d.

In some embodiments, as shown in FIG. 2A to FIG. 2D, the thickness of the second substrate 120a, 120b, 120c, or 120d may be greater than the thickness of the first substrate 110a, 110b, 110c, or 110d. In some embodiments, as shown in FIG. 2A to FIG. 2D, the Young's modulus of the first substrate 110a, 110b, 110c, or 110d may be greater than the Young's modulus of the second substrate 120a, 120b, 120c, or 120d. In some embodiments, as shown in FIG. 2A to FIG. 2D, the ratio of the CTE of the second substrate 120a, 120b, 120c, or 120d to the CTE of the package structure 300 including the molding layer 306 may be in a range of 0.7 to 1.2. In some embodiments, as shown in FIG. 2A to FIG. 2D, the CTE of the first circuit structure CS1 may be greater than the CTE of the first substrate 110a, 110b, 110c, or 110d. In some embodiments, as shown in FIG. 2A to FIG. 2D, the method for manufacturing an electronic device may further include an intermediate layer 115a, 115b, 115c, or 115d between the first substrate 110a, 110b, 110c, or 110d and the second substrate 120a, 120b, 120c, or 120d. In some embodiments, the intermediate layer 115a, 115b, 115c, or 115d may include transparent material.

In some embodiments, as shown in FIG. 2A or FIG. 2D, the method for manufacturing an electronic device may further include providing a second anti-warpage layer WAL2 or a second anti-warpage layer WAL2' on at least another side of the substrate structure 100a or the substrate structure 100d. In some embodiments, as shown in FIG. 2D, the second substrate 120d may be disposed between the second anti-warpage layer WAL2' and the first substrate 110d, and the warpage direction of the second anti-warpage layer WAL2' is opposite to the warpage direction of the first anti-warpage layer WAL1.

In some embodiments, as shown in FIG. 2B, the method for manufacturing an electronic device may further include providing a third substrate 130b between the first substrate 110b and the second substrate 120b, wherein the CTE of the third substrate 130b is greater than the CTE of the second substrate 120b, and the CTE of the first substrate 110b is greater than the CTE of the third substrate 130b. In this embodiment, the thickness of the second substrate 120b may be greater than or equal to the thickness of the third substrate 130b, and the thickness of the third substrate 130b may be greater than or equal to the thickness of the first substrate 110b.

In some other embodiments, as shown in FIG. 2C or FIG. 2D, the method for manufacturing an electronic device may further include providing a third substrate 130c or 130d, wherein the second substrate 120c or 120d is disposed between the first substrate 110c or 110d and the third substrate 130c or 130d, the CTE of the third substrate 130c or 130d is greater than the CTE of the first substrate 110c or 110d, and the CTE of the first substrate 110c or 110d is greater than the CTE of the second substrate 120c or 120d, and the warpage direction of the third substrate 130c or 130d is opposite to the warpage direction of the first substrate 110c or 110d. In this embodiment, the thickness of the second substrate 120c or 120d may be greater than or equal to the thickness of the third substrate 130c or 130d, and the thickness of the third substrate 130c or 130d may be greater than or equal to the thickness of the first substrate 110c or 110d.

In some alternative embodiments, as shown in FIG. 2D, the method for manufacturing an electronic device may further include providing a second anti-warpage layer WAL2' on at least another side of the substrate structure 100d, wherein the third substrate 130d is disposed between the second anti-warpage layer WAL2' and the second substrate 120d, and the warpage direction of the second anti-warpage layer WAL2' is opposite to the warpage direction of the first anti-warpage layer WAL1.

FIG. 3B is a schematic cross-sectional view showing a method for manufacturing an electronic device according to another embodiment of the present disclosure. The manufacturing method shown in FIG. 3B is similar to the manufacturing method shown in FIG. 3A, the differences therebetween are that the package structure 300a shown in FIG. 3B includes a plurality of electronic elements 302 and the first circuit structure CS1a includes wiring structures WS1a respectively connected to the plurality of electronic elements 302. Other same or similar components are represented by the same or similar reference numerals, and will not be repeatedly described herein.

Referring to FIG. 3B, the method for manufacturing an electronic device may include the following steps. Firstly, a first anti-warpage layer WAL1, a de-bond layer DBL, and a first circuit structure CS1a are sequentially provided on a substrate structure 100. Next, a plurality of electronic elements 302 and a plurality of pads 304 of wiring structures WS1a connecting the plurality of electronic elements 302 to the first circuit structure CS1a are provided on the first circuit structure CS1a. Then, a molding layer 306 covering the plurality of electronic elements 302 and the pads 304 is provided on the first circuit structure CS1a to form a package structure 300a. In this embodiment, the molding layer 306 may also cover the de-bond layer DBL and surround the first circuit structure CS1a.

Thereafter, the substrate structure 100, the first anti-warpage layer WAL1, and the de-bond layer DBL are removed to expose the first circuit structure CS1a. In some embodiments, the de-bond layer DBL may be removed, for example, by an ultraviolet de-bond process or other suitable manners to remove the substrate structure 100 and the first anti-warpage layer WAL1 from the first circuit structure CS1a. Thereafter, connection components SB1 electrically connected to the wiring structures WS1a may be formed on the surface of the first circuit structure CS1a from which the de-bond layer DBL has been removed. In some embodiments, the connection components SB1 may include solder balls. In some embodiments, the materials of the connection components SB1 may include tin-silver (SnAg), tin, silver, nickel, gold, copper, conductive adhesive, or other suitable conductive materials, but are not limited thereto. Then, a singulation process may be performed on the package structure 300a and the first circuit structure CS1a to form the electronic device 10 as shown in FIG. 1. In some embodiments, the singulation process may include a step of scribing the package structure 300a and the first circuit structure CS1aalong a scribe line SL1.

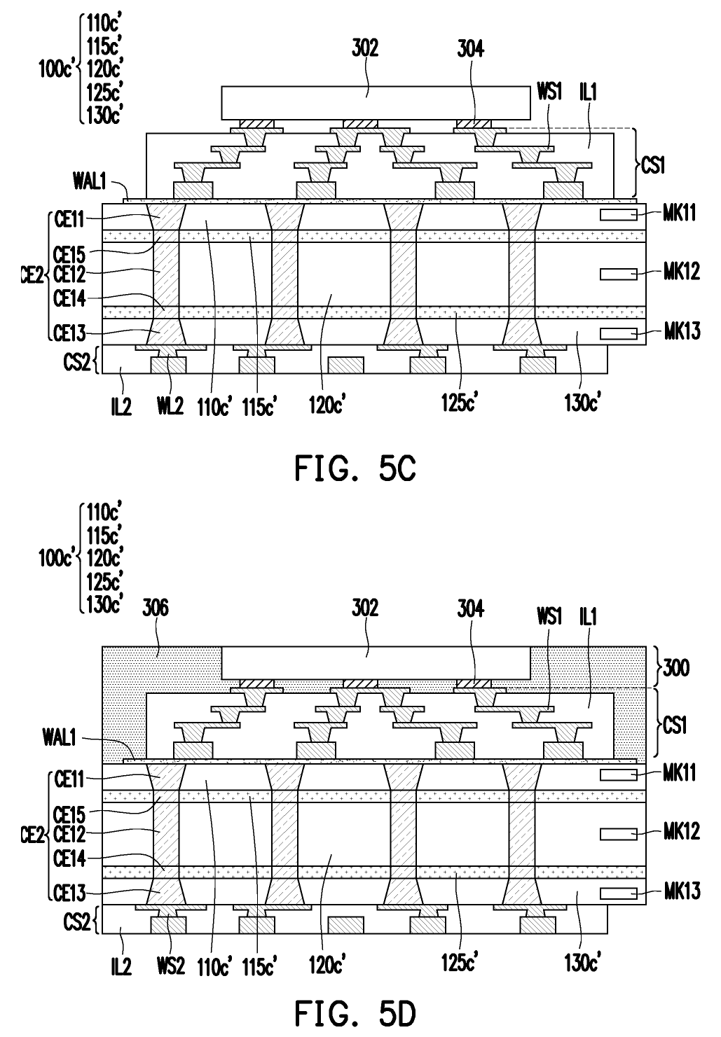

FIG. 4 is a schematic cross-sectional view of an electronic device according to another embodiment of the present disclosure. The electronic device 20 shown in FIG. 4 is similar to the electronic device 10 shown in FIG. 1, the differences therebetween are that the electronic device 20 further includes a second circuit structure CS2 and conductive elements CE1 penetrating through the substrate structure 100d and electrically connecting to the first circuit structure CS1 and the second circuit structure CS2. Other same or similar components are represented by the same or similar reference numerals, and will not be repeatedly described herein.

Referring to FIG. 4, the first circuit structure CS1 and the second circuit structure CS2 of the electronic device 20 are respectively formed on opposite sides of the substrate structure 100d. In this embodiment, the second circuit structure CS2 may be formed on the second anti-warpage layer WAL2', and include an insulation layer IL2 formed on the second anti-warpage layer WAL2' and wiring structures WS2 formed in the insulation layer IL2. The insulation layer IL2 may include a plurality of insulation layers alternately stacked along the direction D1. The wiring structures WS2 may include a plurality of conductive patterns/conductive layers formed in the insulation layer IL2 and alternately stacked along the direction D1, and conductive vias connecting to the conductive patterns/conductive layers. The wiring structures WS2 may include any suitable conductive material, such as copper, titanium, nickel, combinations or alloys of the aforementioned materials, but are not limited thereto. The insulation layer IL2 may include organic materials or inorganic materials. The organic materials may include polyimide (PI), poly-p-xylylene (also known as Parylene), benzocyclobutene (BCB), epoxy, polycarbonate (PC), polyethylene terephthalate (PET), polyethylene naphthalate (PEN), polymers, or other suitable organic materials, but are not limited thereto. The inorganic materials may include silicon oxide, silicon nitride, silicon oxynitride, or other suitable inorganic materials, but are not limited thereto.

In some embodiments, the electronic device 20 may include connection components SB2 formed on the second circuit structure CS2 and electrically connected to the wiring structures WS2. In some embodiments, the connection components SB2 may include solder balls. In some embodiments, the materials of the connection components SB2 may include tin-silver (SnAg), tin, silver, nickel, gold, copper, conductive adhesive, or other suitable conductive materials, but are not limited thereto.

In this embodiment, the conductive elements CE1 may penetrate through the substrate structure 100d and electrically connect the first circuit structure CS1 to the second circuit structure CS2. The conductive elements CE1 may include any suitable conductive material, such as copper, titanium, nickel, combinations or alloys of the aforementioned materials, but are not limited thereto. In some embodiments, the substrate structure 100d may include an alignment mark MK11, an alignment mark MK12, and an alignment mark MK13 respectively formed in the first substrate 110d, the second substrate 120d, and the third substrate 130d, so as to be beneficial for improving the stability of the process for forming the conductive elements CE1.

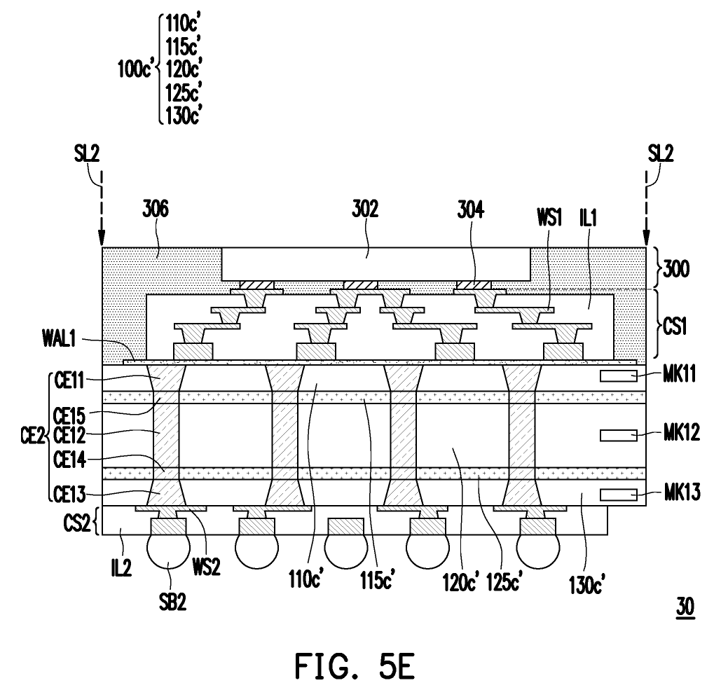

FIG. 5A to FIG. 5E are schematic cross-sectional views showing a method for manufacturing an electronic device according to yet another embodiment of the present disclosure, wherein FIG. 5A is a schematic exploded view of the substrate structure 100c'. It is worth noting that the electronic device 30 shown in FIG. 5E is similar to the electronic device 20 shown in FIG. 4, the differences therebetween are that the substrate structure 100c' and the conductive elements CE2 of the electronic device 30 are different from the substrate structure 100d and the conductive elements CE1 of the electronic device 20. Other same or similar components are denoted by same or similar reference numerals, and will not be repeatedly described herein.

In this embodiment, the manufacturing method of the electronic device (e.g., the electronic device 30 shown in FIG. 5E) may include the following steps.

Firstly, referring to FIG. 5A, a first substrate 110c', a second substrate 120c', a third substrate 130c', an intermediate layer 115c', and an intermediate layer 125c' are provided, wherein the second substrate 120c' is disposed between the first substrate 110c' and the third substrate 130c', and the intermediate layer 115c' and the intermediate layer 125c' are respectively disposed between the first substrate 110c' and the second substrate 120c' and between the second substrate 120c' and the third substrate 130c'.

In this embodiment, the first substrate 110c', the second substrate 120c', and the third substrate 130c' may respectively include conductive vias CE11 penetrating through the first substrate 110c', conductive vias CE12 penetrating through the second substrate 120c', and conductive vias CE13 penetrating through the third substrate 130c'. The conductive vias CE11, the conductive vias CE12, and the conductive vias CE13 may include any suitable conductive material, such as copper, titanium, nickel, combinations or alloys of the aforementioned materials, but are not limited thereto. In this embodiment, the intermediate layer 115c' may have opening patterns corresponding to the conductive vias CE11 and the conductive vias CE12, and the intermediate layer 125c' may have opening patterns corresponding to the conductive vias CE12 and the conductive vias CE13.

Next, referring to FIG. 5B, the first substrate 110c', the second substrate 120c', the third substrate 130c', the intermediate layer 115c', and the intermediate layer 125c' shown in FIG. 5A are laminated together and a heating process is performed thereafter to form conductive pads CE15 connecting to the conductive vias CE11 and the conductive vias CE12 in the opening patterns of the intermediate layer 115c', and to form conductive pads CE14 connecting to the conductive vias CE12 and the conductive vias CE13 in the opening patterns of the intermediate layer 125c', thereby forming conductive elements CE2 including the conductive vias CE11, the conductive vias CE12, the conductive vias CE13, the conductive pads CE14, and the conductive pads CE15 and penetrating through the substrate structure 100c'. In this embodiment, the opening patterns of the intermediate layer 115c' and the intermediate layer 125c' may be used to define the positions for forming the conductive pads CE14 and the conductive pads CE15.

Then, referring to FIG. 5B and FIG. 5C, a first circuit structure CS1 and a second circuit structure CS2 are respectively formed on the first substrate 110c' and the third substrate 130c'. Next, an electronic element 302 and a plurality of pads 304 connecting the electronic element 302 to the first circuit structure CS1 are provided on the first circuit structure CS1.

Then, referring to FIG. 5C and FIG. 5D, a molding layer 306 covering the electronic element 302 and the pads 304 is provided on the first circuit structure CS1 to form a package structure 300. In this embodiment, the molding layer 306 may also cover the first substrate 110c' and surround the first circuit structure CS1. Then, a singulation process may be performed on the package structure 300, the first circuit structure CS1, the substrate structure 100c', and the second circuit structure CS2 to form the electronic device 30. In some embodiments, the singulation process may include a step of scribing the package structure 300, the first circuit structure CS1, the substrate structure 100c', and the second circuit structure CS2 along the scribe lines SL2.

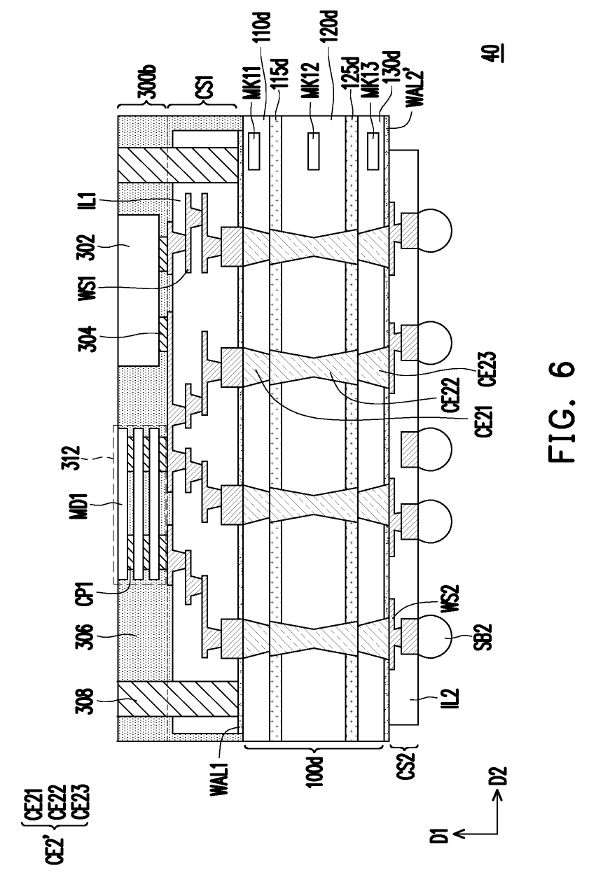

FIG. 6 is a schematic cross-sectional view of an electronic device according to yet another embodiment of the present disclosure. It is worth noting that the electronic device 40 shown in FIG. 6 is similar to the electronic device 20 shown in FIG. 4, with the difference being that the package structure 300b and the conductive element CE2' of the electronic device 40 are different from the package structure 300 and the conductive element CE1 of the electronic device 20. Other identical or similar components are denoted by identical or similar reference numerals and will not be repeatedly described herein.

Referring to FIG. 6, the package structure 300b of the electronic device 40 includes an electronic element 302 and an electronic element 312 formed on the first circuit structure CS1. In this embodiment, the electronic element 312 includes dies MD1 (e.g., memory dies) stacked on each other and conductive pads CP1 connecting the dies MD1 to each other. The conductive element CE2' may include conductive vias CE21, conductive vias CE22, and conductive vias CE23 respectively penetrating through the first substrate 110d, the second substrate 120d, and the third substrate 130d. In some embodiments, the package structure 300b of the electronic device 40 further includes dummy structures 308 penetrating through the molding layer 306 and the insulation layer IL1.

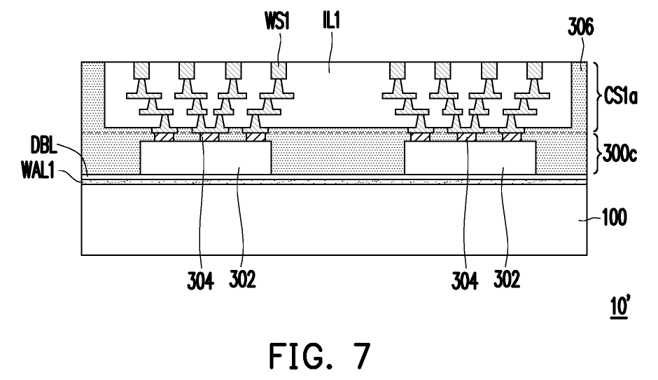

FIG. 7 is a schematic cross-sectional view of an electronic device according to still another embodiment of the present disclosure. It is worth noting that the electronic device 10' shown in FIG. 7 is similar to the electronic device 10 shown in FIG. 1, with the difference being that the package structure 300c of the electronic device 10' is firstly formed above the substrate structure 100, and then the first circuit structure CS1a is formed on the package structure 300c. Other identical or similar components are denoted by identical or similar reference numerals and will not be repeatedly described herein.

Referring to FIG. 7, the electronic device 10' may include a substrate structure 100, a first anti-warpage layer WAL1, a de-bond layer DBL, a package structure 300c, and a first circuit structure CS1a. In this embodiment, the first anti-warpage layer WAL1 and the de-bond layer DBL are sequentially formed on the substrate structure 100. Then, the package structure 300c is provided on the de-bond layer DBL. Next, the first circuit structure CS1a is provided on the package structure 300c. That is, the electronic device 10' shown in FIG. 7 may be formed through, for example, a chip-first process.

In summary, in the embodiments of the present disclosure, the CTE of the first substrate disposed between the first circuit structure and the second substrate is configured to be greater than the CTE of the second substrate, so that the first substrate, the second substrate, and the first circuit structure exhibit a gradual change in CTE, and thus is beneficial for reducing the warpage caused by the excessive difference in CTE, so as to improve the reliability of the electronic device.

The above embodiments are used to illustrate the technical solution of the disclosure, and are not intended to limit the same. Although the disclosure has been described in detail with reference to the above embodiments, a person skilled in the art should understand that modifications may still be made to the technical solutions described in the above embodiments, or equivalent replacements may be made for some or all of the technical features. These modifications or replacements do not cause the essence of the corresponding technical solutions to depart from the scope of the technical solutions of the embodiments of the disclosure. The features among the embodiments may be arbitrarily combined and used as long as they do not violate or conflict with the spirit of the invention.

Although the embodiments of the disclosure and the advantages thereof have been disclosed as above, it should be understood that a person skilled in the art may make changes, substitutions, and modifications without departing from the spirit and scope of the disclosure, and the features among the embodiments may be arbitrarily mixed and replaced to form other new embodiments. In addition, the scope of protection of the disclosure is not limited to the processes, machines, manufacturing, compositions of matter, devices, methods, and steps described in the specific embodiments in the specification. A person skilled in the art may understand from the disclosure of the disclosure the existing or future developed processes, machines, manufacturing, compositions of matter, devices, methods, and steps, as long as substantially the same functions may be implemented or substantially the same results may be obtained in the embodiments described herein, all may be used according to the disclosure. Therefore, the scope of protection of the disclosure includes the above processes, machines, manufacturing, compositions of matter, devices, methods, and steps. In addition, each claim constitutes a separate embodiment, and the scope of protection of the disclosure also includes combinations of the respective claims and embodiments. The scope of protection of the disclosure shall be subject to the appended claims.

What is claimed is:

1. A method for manufacturing an electronic device, comprising:
providing a substrate structure, wherein the substrate structure comprises a first substrate and a second substrate;
providing a first anti-warpage layer on at least one side of the substrate structure;
forming a first circuit structure on the first substrate; and
forming a package structure on the first circuit structure,
wherein the first substrate is disposed between the first circuit structure and the second substrate and a coefficient of thermal expansion (CTE) of the first substrate is greater than a CTE of the second substrate.

2. The method for manufacturing the electronic device according to claim 1, wherein a thickness of the second substrate is greater than a thickness of the first substrate.

3. The method for manufacturing the electronic device according to claim 1, wherein a Young's modulus of the first substrate is greater than a Young's modulus of the second substrate.

4. The method for manufacturing the electronic device according to claim 1, further comprising:
providing a second anti-warpage layer on at least another side of the substrate structure.

5. The method for manufacturing the electronic device according to claim 4, wherein the second substrate is disposed between the second anti-warpage layer and the first substrate, and a warpage direction of the second anti-warpage layer is opposite to a warpage direction of the first anti-warpage layer.

6. The method for manufacturing the electronic device according to claim 1, further comprising:
providing an intermediate layer between the first substrate and the second substrate, and the intermediate layer comprises a transparent material.

7. The method for manufacturing the electronic device according to claim 1, further comprising:
providing a third substrate between the first substrate and the second substrate, wherein a CTE of the third substrate is greater than the CTE of the second substrate, and the CTE of the first substrate is greater than the CTE of the third substrate.

8. The method for manufacturing the electronic device according to claim 7, wherein a thickness of the second substrate is greater than or equal to a thickness of the third substrate, and the thickness of the third substrate is greater than or equal to a thickness of the first substrate.

9. The method for manufacturing the electronic device according to claim 1, further comprising:
providing a third substrate, wherein the second substrate is disposed between the first substrate and the third substrate, a CTE of the third substrate is greater than the CTE of the first substrate, and the CTE of the first substrate is greater than the CTE of the second substrate, and
a warpage direction of the third substrate is opposite to a warpage direction of the first substrate.

10. The method for manufacturing the electronic device according to claim 9, wherein a thickness of the second substrate is greater than or equal to a thickness of the third substrate, and the thickness of the third substrate is greater than or equal to a thickness of the first substrate.

11. The method for manufacturing the electronic device according to claim 10, further comprising:
providing a second anti-warpage layer on at least another side of the substrate structure, wherein the third substrate is disposed between the second anti-warpage layer and the second substrate, and a warpage direction of the second anti-warpage layer is opposite to a warpage direction of the first anti-warpage layer.

12. The method for manufacturing the electronic device according to claim 1, wherein a ratio of the CTE of the second substrate to a CTE of the package structure comprising a molding layer is in a range of 0.7 to 1.2.

13. The method for manufacturing the electronic device according to claim 1, wherein a CTE of the first circuit structure is greater than the CTE of the first substrate.

14. An electronic device, comprising:
a substrate structure comprising a first substrate and a second substrate;
a first anti-warpage layer disposed on at least one side of the substrate structure;
a first circuit structure disposed on the first substrate; and
a package structure disposed on the first circuit structure,
wherein the first substrate is disposed between the first circuit structure and the second substrate, and a CTE of the first substrate is greater than a CTE of the second substrate.

15. The electronic device according to claim 14, wherein a thickness of the second substrate is greater than a thickness of the first substrate.

16. The electronic device according to claim 14, wherein a Young's modulus of the first substrate is greater than a Young's modulus of the second substrate.

17. The electronic device according to claim 14, wherein the substrate structure further comprises:
a third substrate disposed between the first substrate and the second substrate, wherein a CTE of the third substrate is greater than the CTE of the second substrate, and the CTE of the first substrate is greater than the CTE of the third substrate.

18. The electronic device according to claim 17, wherein a thickness of the second substrate is greater than or equal to a thickness of the third substrate, and the thickness of the third substrate is greater than or equal to a thickness of the first substrate.

19. The electronic device according to claim 14, wherein the substrate structure further comprises:
a third substrate, wherein the second substrate is disposed between the first substrate and the third substrate, a CTE of the third substrate is greater than the CTE of the first substrate, and the CTE of the first substrate is greater than the CTE of the second substrate, and
a warpage direction of the third substrate is opposite to a warpage direction of the first substrate.

20. The electronic device according to claim 19, wherein a thickness of the second substrate is greater than or equal to a thickness of the third substrate, and the thickness of the third substrate is greater than or equal to a thickness of the first substrate.
